(19) United States
(12) Patent Application Publication
(10) Pub. No.: US 2020/0192224 A1
(43) Pub. Date: Jun. 18, 2020

(54) RESIST UNDERLAYER FILM-FORMING COMPOSITION

(71) Applicant: NISSAN CHEMICAL CORPORATION, Tokyo (JP)

(72) Inventors: Hiroto OGATA, Toyama-shi (JP); Yuki USUI, Toyama-shi (JP); Masahisa ENDO, Toyama-shi (JP); Takahiro KISHIOKA, Toyama-shi (JP)

(73) Assignee: NISSAN CHEMICAL CORPORATION, Tokyo (JP)

(21) Appl. No.: 16/641,371

(22) PCT Filed: Aug. 14, 2018
(86) PCT No.: PCT/JP2018/030292

§ 371 Date: Feb. 24, 2020

(30) Foreign Application Priority Data
Aug. 24, 2017 (JP) 2017-161480

(51) Int. Cl. G03F 7/11; C09D 181/02; H01L 21/027

(52) U.S. Cl. CPC G03F 7/11; G03F 7/162; H01L 21/0274; C09D 181/02

(57) ABSTRACT

A resist underlayer film-forming composition including a solvent and a copolymer including a structural unit of the following Formula (1):

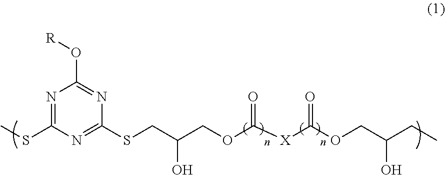

wherein X is a divalent chain hydrocarbon group having a carbon atom number of 2 to 10, and the divalent chain hydrocarbon group optionally has at least one sulfur atom or oxygen atom in a main chain, or optionally has at least one hydroxy group as a substituent; R is a chain hydrocarbon group having a carbon atom number of 1 to 10; and each n is 0 or 1.

### TECHNICAL FIELD

The present invention relates to a composition for forming a resist underlayer film that has a high dry etching rate, functions as an anti-reflective coating during light exposure using any of ArF excimer laser and KrF excimer laser as a light source, and has the ability to fill recesses.

### BACKGROUND ART

For example, a known method for producing a semiconductor device involves formation of a fine resist pattern on a substrate by a photolithographic technique including a light exposure process using KrF excimer laser or ArF excimer laser as a light source. Before formation of the resist pattern, KrF excimer laser or ArF excimer laser incident on a resist film (i.e., incident light) is reflected on the surface of the substrate, to thereby generate a standing wave in the resist film. It is known that the standing wave prevents formation of a resist pattern having a desired shape. In a known process for preventing generation of the standing wave, an anti-reflective coating that absorbs incident light is provided between the resist film and the substrate. In the case where the anti-reflective coating is provided as an underlayer of the resist film, the anti-reflective coating is required to have a dry etching rate higher than that of the resist film.

Patent Documents 1 and 2 disclose a resist underlayer film-forming composition or anti-reflective coating-forming composition containing a polymer including a structural unit having at least one sulfur atom. The use of the composition disclosed in Patent Documents 1 and 2 can form a resist underlayer film or anti-reflective coating having a dry etching rate higher than that of a resist film. A method for producing a semiconductor device by using a substrate having recesses on its surface requires a gap-filling material or planarization film having the ability to fill the recesses of the substrate. However, Patent Documents 1 and 2 neither describe nor suggest recess-filling property.

Patent Document 3 discloses a resist underlayer film-forming composition containing a copolymer having a triazine ring and a sulfur atom in a main chain. The use of the composition disclosed in Patent Document 3 can form a resist underlayer film that has a dry etching rate much higher than that of a resist film, functions as an anti-reflective coating during light exposure without reduction in dry etching rate, and has the ability to fill holes (diameter: 0.12 μm, depth: 0.4 μm) of a semiconductor substrate.

### PRIOR ART DOCUMENTS

### Patent Documents

Patent Document 1: International Publication WO 2009/096340

Patent Document 2: International Publication WO 2006/040918

Patent Document 3: International Publication WO 2015/098525

### SUMMARY OF THE INVENTION

### Problems to be Solved by the Invention

The production of a semiconductor device requires a resist underlayer film satisfying all the following requirements: having a high dry etching rate; functioning as an anti-reflective coating during light exposure using any of ArF excimer laser and KrF excimer laser as a light source; and having the ability to fill recesses of a semiconductor substrate.

### Means for Solving the Problems

The present invention solves the aforementioned problems by providing a resist underlayer film-forming composition comprising a solvent and a copolymer including, in its main chain, a triazine ring having an alkoxy group as a substituent. Accordingly, a first aspect of the present invention is a resist underlayer film-forming composition comprising a solvent and a copolymer including a structural unit of the following Formula (1):

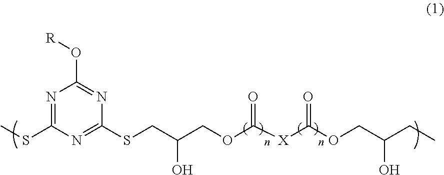

(wherein X is a divalent chain hydrocarbon group having a carbon atom number of 2 to 10, and the divalent chain hydrocarbon group optionally has at least one sulfur atom or oxygen atom in a main chain, or optionally has at least one hydroxy group as a substituent; R is a chain hydrocarbon group having a carbon atom number of 1 to 10; and each n is 0 or 1).

The copolymer is, for example, a reaction product between a dithiol compound of the following Formula (2) and a diglycidyl ether compound or diglycidyl ester compound of the following Formula (3):

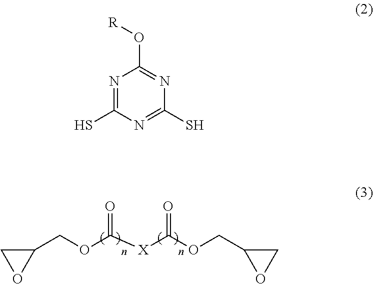

(wherein X, R, and each n have the same meanings as defined above in Formula (1)).

The resist underlayer film-forming composition of the present invention may further comprise at least one of a crosslinkable compound, a thermal acid generator, and a surfactant.

A second aspect of the present invention is a method for forming a photoresist pattern used for production of a semiconductor device, the method comprising a step of applying the resist underlayer film-forming composition according to the first aspect of the present invention onto a semiconductor substrate having a recess on its surface, and then baking the composition, to thereby form a resist underlayer film that fills at least the recess; a step of forming a photoresist layer on the resist underlayer film; a step of exposing, to light, the semiconductor substrate coated with the resist underlayer film and the photoresist layer; and a step of developing the photoresist layer after the light exposure.

### Effects of the Invention

The following effects are achieved by using the resist underlayer film-forming composition of the present invention.

(1) The copolymer contained in the resist underlayer film-forming composition of the present invention has an alkoxy group, and the copolymer has a sulfur atom in its main chain. Thus, the composition can form a resist underlayer film having a dry etching rate much higher than that of a resist film and higher than that of a conventional resist underlayer film.

(2) The copolymer contained in the resist underlayer film-forming composition of the present invention has an alkoxy group and also has a triazine ring. Thus, the composition can form a resist underlayer film that functions as an anti-reflective coating during light exposure using any of ArF excimer laser and KrF excimer laser as a light source without reduction in dry etching rate.

(3) Since the copolymer contained in the resist underlayer film-forming composition of the present invention has an alkoxy group instead of a dialkylamino group, a resist underlayer film formed from the resist underlayer film-forming composition has basicity lower than that of a conventional resist underlayer film formed from a conventional resist underlayer film-forming composition containing a copolymer having a dialkylamino group. Thus, a photoresist pattern formed on the former resist underlayer film does not have a skirt-shaped cross section, but has a rectangular cross section.

(4) The amount of a sublimate generated during formation of a resist underlayer film from the resist underlayer film-forming composition of the present invention can be reduced as compared with the amount of a sublimate generated during formation of a resist underlayer film from a conventional resist underlayer film-forming composition containing a copolymer having a dialkylamino group.

(5) The resist underlayer film-forming composition of the present invention can form a resist underlayer film having the ability to fill recesses of a semiconductor substrate.

### BRIEF DESCRIPTION OF THE DRAWINGS

FIG. 1 is an SEM image of a cross section of a photoresist pattern formed on a resist underlayer film formed from a resist underlayer film-forming composition of Example 2.

FIG. 2 is an SEM image of a cross section of a photoresist pattern formed on a resist underlayer film formed from a resist underlayer film-forming composition of Comparative Example 2.

FIG. 3 is a schematic cross-sectional view of an SiO₂ wafer used in a test for the trench-filling property (fillability) of a resist underlayer film.

FIG. 4 is an SEM image of a cross section of an SiO₂ wafer having trenches filled with a resist underlayer film formed from a resist underlayer film-forming composition of Example 1.

FIG. 5 is an SEM image of a cross section of an SiO₂ wafer having trenches filled with a resist underlayer film formed from a resist underlayer film-forming composition of Example 2.

### MODES FOR CARRYING OUT THE INVENTION

The copolymer contained in the resist underlayer film-forming composition of the present invention is synthesized by, for example, reaction between a dithiol compound of Formula (2) and a diglycidyl ether compound or diglycidyl ester compound of Formula (3). Examples of the dithiol compound of Formula (2) include compounds of the following Formulae (2a) to (21).

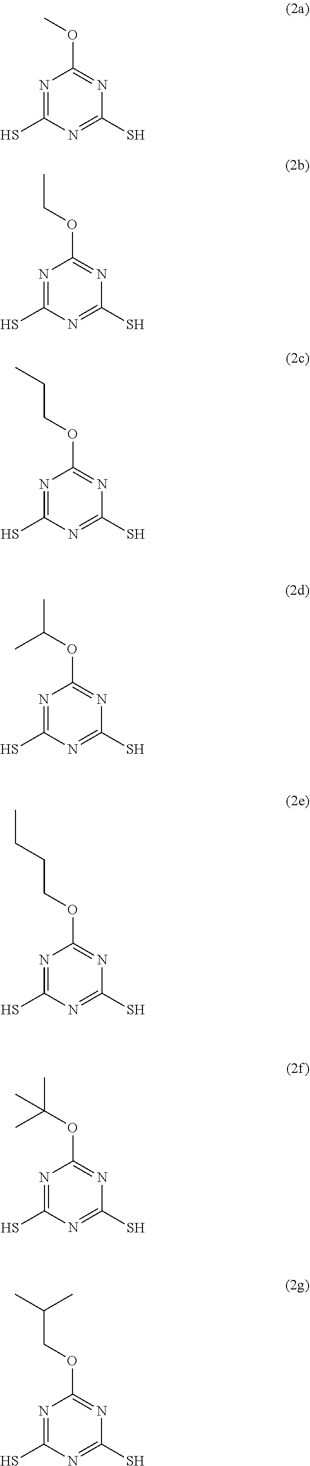

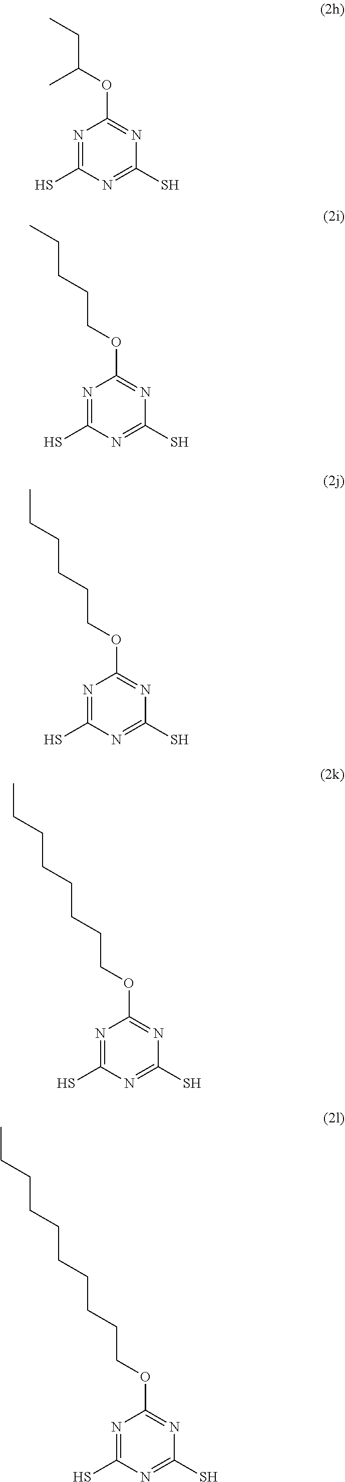

Examples of the diglycidyl ether compound or diglycidyl ester compound of Formula (3) include compounds of the following Formulae (3a) to (31).

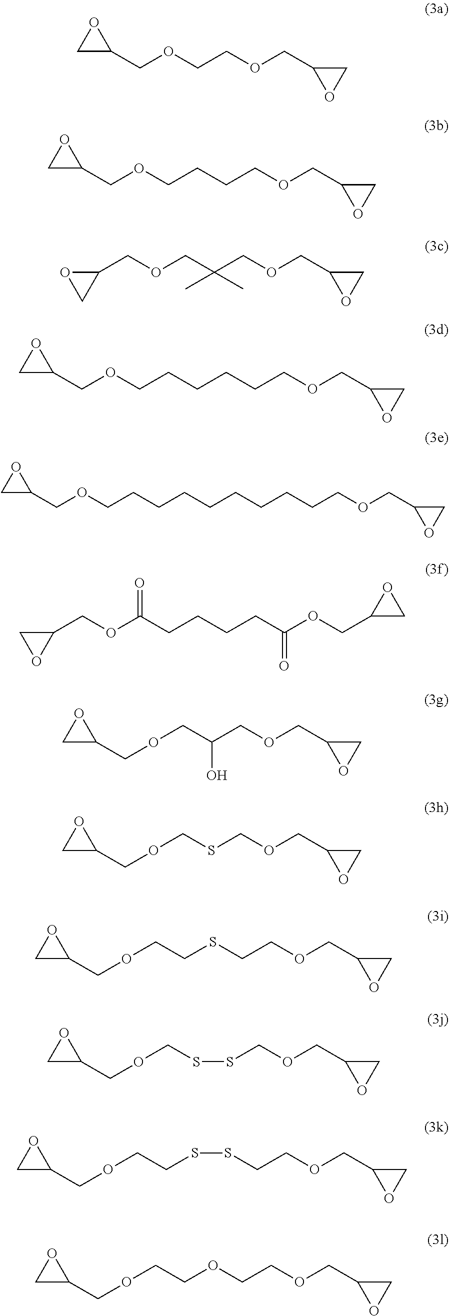

The aforementioned copolymer has a weight average molecular weight of, for example, 1,000 to 100,000, preferably 1,000 to 30,000. A weight average molecular weight of the copolymer of less than 1,000 may lead to insufficient solvent resistance. The weight average molecular weight is determined by gel permeation chromatography (hereinafter abbreviated as “GPC”) using polystyrene as a standard sample.

The resist underlayer film-forming composition of the present invention may contain a crosslinkable compound. The crosslinkable compound is also called a crosslinking agent. The crosslinkable compound is preferably a compound having at least two crosslinkable substituents. Examples of the compound include a melamine compound, substituted urea compound, or aromatic compound having at least two crosslinkable substituents, such as a hydroxymethyl group and an alkoxymethyl group; a compound having at least two epoxy groups; and a compound having at least two blocked isocyanate groups. Examples of the alkoxymethyl group include methoxymethyl group, 2-methoxyethoxymethyl group, and butoxymethyl group. The crosslinkable compound is more preferably a nitrogen-containing compound having at least two (e.g., two to four) nitrogen atoms to which a hydroxymethyl group or an alkoxymethyl group is bonded. Examples of the nitrogen-containing compound include hexamethoxymethylmelamine, tetramethoxymethylbenzoguanamine, 1,3,4,6-tetrakis(methoxymethyl)glycoluril, 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

Examples of the aromatic compound having at least two hydroxymethyl groups or alkoxymethyl groups include 1-hydroxybenzene-2,4,6-trimethanol, 3,3′,5,5′-tetrakis(hydroxymethyl)-4,4′-dihydroxybiphenyl (trade name: TML-BP, available from Honshu Chemical Industry Co., Ltd.), 5,5′-[2,2,2-trifluoro-1-(trifluoromethyl)ethylidene]bis[2-hydroxy-1,3-benzenedimethanol] (trade name: TML-BPAF-MF, available from Honshu Chemical Industry Co., Ltd.), 2,2-dimethoxymethyl-4-t-butylphenol (trade name: DMOM-PTBP, available from Honshu Chemical Industry Co., Ltd.), 3,3′,5,5′-tetramethoxymethyl-4,4′-dihydroxybiphenyl (trade name: TMOM-BP, available from Honshu Chemical Industry Co., Ltd.), bis(2-hydroxy-3-hydroxymethyl-5-methylphenyl)methane (trade name: DM-BIPC-F, available from ASAHI YUKIZAI CORPORATION), bis(4-hydroxy-3-hydroxymethyl-5-methylphenyl)methane (trade name: DM-BIOC-F, available from ASAHI YUKIZAI CORPORATION), and 5,5′-(1-methylethylidene)bis(2-hydroxy-1,3-benzenedimethanol) (trade name: TM-BIP-A, available from ASAHI YUKIZAI CORPORATION).

Examples of the compound having at least two epoxy groups include tris(2,3-epoxypropyl) isocyanurate, 1,4-butanediol diglycidyl ether, 1,2-epoxy-4-(epoxyethyl)cyclohexane, glycerol triglycidyl ether, diethylene glycol diglycidyl ether, 2,6-diglycidyl phenyl glycidyl ether, 1,1,3-tris[p-(2,3-epoxypropoxy)phenyl]propane, 1,2-cyclohexanedicarboxylic acid diglycidyl ester, 4,4′-methylenebis(N,N-diglycidylaniline), 3,4-epoxycyclohexylmethyl-3,4-epoxycyclohexane carboxylate, trimethylolethane triglycidyl ether, bisphenol-A-diglycidyl ether, Epoleed [registered trademark] GT-401, GT-403, GT-301, and GT-302 and Celloxide [registered trademark] 2021 and 3000 available from Daicel Corporation, 1001, 1002, 1003, 1004, 1007, 1009, 1010, 828, 807, 152, 154, 180S75, 871, and 872 available from Mitsubishi Chemical Corporation, EPPN201, EPPN202, EOCN-102, EOCN-103S, EOCN-104S, EOCN-1020, EOCN-1025, and EOCN-1027 available from Nippon Kayaku Co., Ltd., Denacol [registered trademark] EX-252, EX-611, EX-612, EX-614, EX-622, EX-411, EX-512, EX-522, EX-421, EX-313, EX-314, and EX-321 available from Nagase ChemteX Corporation, CY175, CY177, CY179, CY182, CY184, and CY192 available from BASF Japan Ltd., and EPICLON 200, 400, 7015, 835LV, and 850CRP available from DIC Corporation.

The compound having at least two epoxy groups may be a polymer compound. No particular limitation is imposed on the polymer compound, so long as it is a polymer having at least two epoxy groups. The polymer compound can be produced by addition polymerization of an addition-polymerizable monomer having an epoxy group, or by reaction between a polymer having a hydroxy group and a compound having an epoxy group, such as epichlorohydrin or glycidyl tosylate. Examples of the polymer having at least two epoxy groups include addition polymerization polymers, such as polyglycidyl acrylate, copolymers of glycidyl methacrylate with ethyl methacrylate, and copolymers of glycidyl methacrylate with styrene and 2-hydroxyethyl methacrylate; and polycondensation polymers, such as epoxy novolac. The polymer compound has a weight average molecular weight of, for example, 300 to 200,000. The weight average molecular weight is determined by GPC using polystyrene as a standard sample.

The compound having at least two epoxy groups may also be an epoxy resin having an amino group. Examples of the epoxy resin include YH-434 and YH-434L (available from NSCC Epoxy Manufacturing Co., Ltd.).

Examples of the compound having at least two blocked isocyanate groups include Takenate [registered trademark] B-830 and B-870N available from Mitsui Chemicals, Incorporated, and VESTANAT [registered trademark]-B1358/100 available from Evonik Degussa.

These exemplified compounds may be used alone or in combination of two or more species.

When the aforementioned crosslinkable compound is used, the amount thereof is, for example, 1% by mass to 80% by mass, preferably 10% by mass to 60% by mass, relative to the amount of the aforementioned copolymer. When the amount of the crosslinkable compound is excessively small and excessively large, the resultant film may have insufficient resistance against a resist solvent.

The resist underlayer film-forming composition of the present invention may contain a crosslinking catalyst together with the aforementioned crosslinkable compound in order to promote a crosslinking reaction. The crosslinking catalyst may be, for example, a sulfonic acid compound, a carboxylic acid compound, or a thermal acid generator. Examples of the sulfonic acid compound include p-toluenesulfonic acid, pyridinium-p-toluenesulfonate, 5-sulfosalicylic acid, 4-chlorobenzenesulfonic acid, 4-hydroxybenzenesulfonic acid, pyridinium-4-hydroxybenzenesulfonate, n-dodecylbenzenesulfonic acid, 4-nitrobenzenesulfonic acid, benzenedisulfonic acid, 1-naphthalenesulfonic acid, trifluoromethanesulfonic acid, and camphorsulfonic acid. Examples of the carboxylic acid compound include salicylic acid, citric acid, benzoic acid, and hydroxybenzoic acid. Examples of the thermal acid generator include K-PURE [registered trademark] CXC-1612, CXC-1614, TAG-2172, TAG-2179, TAG-2678, and TAG2689 (available from King Industries Inc.) and SI-45, SI-60, SI-80, SI-100, SI-110, and SI-150 (available from SANSHIN CHEMICAL INDUSTRY CO., LTD.).

These crosslinking catalysts may be used alone or in combination of two or more species. When such a crosslinking catalyst is used, the amount thereof is, for example, 1% by mass to 40% by mass, preferably 5% by mass to 20% by mass, relative to the amount of the aforementioned crosslinkable compound.

The resist underlayer film-forming composition of the present invention may contain a glycoluril derivative having four functional groups together with the aforementioned crosslinkable compound. Examples of the glycoluril derivative include 1,3,4,6-tetraallylglycoluril (trade name: TA-G, available from SHIKOKU CHEMICALS CORPORATION), 1,3,4,6-tetraglycidylglycoluril (trade name: TG-G, available from SHIKOKU CHEMICALS CORPORATION), 1,3,4,6-tetrakis(2-carboxyethyl)glycoluril (trade name: TC-G, available from SHIKOKU CHEMICALS CORPORATION), 1,3,4,6-tetrakis(2-hydroxyethyl)glycoluril (trade name: TH-G, available from SHIKOKU CHEMICALS CORPORATION), and 1,3,4,6-tetrakis(2-mercaptoethyl)glycoluril (trade name: TS-G, available from SHIKOKU CHEMICALS CORPORATION).

These glycoluril derivatives may be used alone or in combination of two or more species. When such a glycoluril derivative is used, the amount thereof is, for example, 1% by mass to 40% by mass, preferably 5% by mass to 30% by mass, relative to the amount of the aforementioned copolymer.

The resist underlayer film-forming composition of the present invention may contain a surfactant for improving the applicability of the composition to a substrate. Examples of the surfactant include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylaryl ethers, such as polyoxyethylene octylphenyl ether and polyoxyethylene nonylphenyl ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as EFTOP [registered trademark] EF301, EF303, and EF352 (available from Mitsubishi Materials Electronic Chemicals Co., Ltd.), MEGAFAC [registered trademark] F171, F173, R-30, R-30N, and R-40-LM (available from DIC Corporation), Fluorad FC430 and FC431 (available from 3M Japan Limited), Asahi Guard [registered trademark] AG710, and SURFLON [registered trademark] S-382, SC101, SC102, SC103, SC104, SC105, and SC106 (available from Asahi Glass Co., Ltd.); and Organosiloxane Polymer KP341 (available from Shin-Etsu Chemical Co., Ltd.).

These surfactants may be used alone or in combination of two or more species. When such a surfactant is used, the amount thereof is, for example, 0.01% by mass to 5% by mass, preferably 0.1% by mass to 3% by mass, relative to the amount of the aforementioned copolymer.

The resist underlayer film-forming composition of the present invention can be prepared by dissolving the aforementioned components in an appropriate solvent, and is used in the form of a homogeneous solution. Examples of the solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, and N-methylpyrrolidone.

These solvents may be used alone or in combination of two or more species. Furthermore, such a solvent may be mixed with a high boiling point solvent such as propylene glycol monobutyl ether or propylene glycol monobutyl ether acetate.

Next will be described the use of the resist underlayer film-forming composition of the present invention. The composition of the present invention is applied onto a substrate having recesses (for example, a semiconductor substrate (e.g., a silicon wafer or a germanium wafer) that may be coated with a silicon oxide film, a silicon nitride film, or a silicon oxide nitride film) by an appropriate application method using, for example, a spinner or a coater. Thereafter, the composition is baked by heating means (e.g., a hot plate) to thereby form a resist underlayer film. The baking is performed under appropriately determined conditions; i.e., a baking temperature of 80° C. to 250° C. and a baking time of 0.3 minutes to 10 minutes. Preferably, the baking temperature is 120° C. to 250° C., and the baking time is 0.5 minutes to 5 minutes. The resist underlayer film has a thickness of 0.005 μm to 3.0 μm, for example, 0.01 μm to 0.2 μm or 0.05 μm to 0.5 μm.

A baking temperature below the aforementioned range may lead to insufficient crosslinking, resulting in intermixing of the resist underlayer film with a resist film formed on the resist underlayer film. Meanwhile, a baking temperature above the aforementioned range may lead to breakage of a crosslink, resulting in intermixing of the resist underlayer film with the resist film

Subsequently, a resist film is formed on the resist underlayer film. The resist film can be formed by a common method; specifically, a method involving application of a photoresist solution onto the resist underlayer film, and baking of the photoresist.

No particular limitation is imposed on the photoresist solution used for formation of the resist film, so long as the photoresist is sensitive to a light source used for exposure. The photoresist used may be a negative or positive photoresist.

For formation of a resist pattern, light exposure is performed through a mask (reticle) for forming a predetermined pattern. The light exposure can be performed with, for example, KrF excimer laser or ArF excimer laser. Post exposure bake is optionally performed after the light exposure. “Post exposure bake” is performed under appropriately determined conditions; i.e., a heating temperature of 80° C. to 150° C. and a heating time of 0.3 minutes to 10 minutes. Thereafter, the light-exposed film is developed with an alkaline developer, to thereby form a resist pattern.

Example of the alkaline developer include alkaline aqueous solutions, for example, aqueous solutions of alkali metal hydroxides, such as potassium hydroxide and sodium hydroxide; aqueous solutions of quaternary ammonium hydroxides, such as tetramethylammonium hydroxide, tetraethylammonium hydroxide, and choline; and aqueous solutions of amines, such as ethanolamine, propylamine, and ethylenediamine. Such a developer may also contain, for example, a surfactant. The development is performed under appropriately determined conditions; i.e., a development temperature of 5° C. to 50° C. and a development time of 10 seconds to 300 seconds.

### EXAMPLES

The resist underlayer film-forming composition of the present invention will next be described in detail by way of the following examples, which should not be construed as limiting the invention thereto.

The following apparatus, etc. were used for measurement of the weight average molecular weights of reaction products prepared in Synthesis Examples described below.

Apparatus: HLC-8320GPC available from TOSOH CORPORATION

GPC column: Asahipak [registered trademark] GF-310HQ, GF-510HQ, and GF-710HQ

Column temperature: 40° C.

Flow rate: 0.6 ml/min

Eluent: DMF

Standard sample: polystyrene

### Synthesis Example 1

To 16.58 g of propylene glycol monomethyl ether (hereinafter abbreviated as “PGME”) were added 2.05 g of 2-butoxy-4,6-dithiol-1,3,5-triazine, 2.00 g of 1,4-butanediol diglycidyl ether, and 0.92 g of ethyltriphenylphosphonium bromide serving as a catalyst, and then reaction was allowed to proceed at 25 to 30° C. for 24 hours, to thereby prepare a solution containing a reaction product. The resultant reaction product was subjected to GPC analysis, and the product was found to have a weight average molecular weight of 9,700 in terms of standard polystyrene. The reaction product is assumed to be a copolymer having a structural unit of the following Formula (1a).

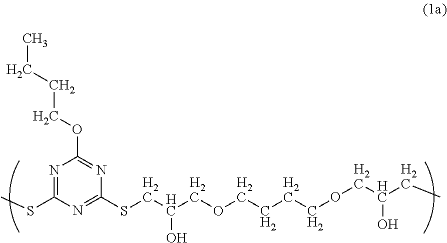

### Synthesis Example 2

To 139.94 g of PGME were added 19.29 g of 2-dibutylamino-4,6-dithiol-1,3,5-triazine, 15.00 g of 1,4-butanediol diglycidyl ether, and 0.69 g of ethyltriphenylphosphonium bromide serving as a catalyst, and then reaction was allowed to proceed at 25 to 30° C. for 24 hours, to thereby prepare a solution containing a reaction product. The resultant reaction product was subjected to GPC analysis, and the product was found to have a weight average molecular weight of 26,000 in terms of standard polystyrene. The reaction product is assumed to be a copolymer having a structural unit of the following Formula (4).

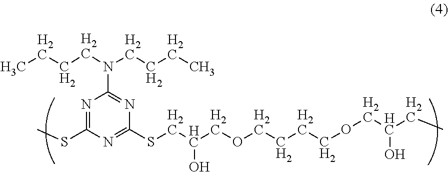

### Preparation of Resist Underlayer Film-Forming Composition

### Example 1

To 2.07 g of the solution containing 0.35 g of the copolymer prepared in Synthesis Example 1 (solvent: PGME used for the synthesis) were added 7.82 g of PGME, 1.12 g of propylene glycol monomethyl ether acetate, 0.087 g of 1,3,4,6-tetrakis(methoxymethyl)glycoluril (trade name: Powderlink 1174, available from Nihon Cytec Industries Inc.), 0.0087 g of pyridinium-p-toluenesulfonate, and 0.00035 g of a surfactant (trade name: R-30N, available from DIC Corporation). These materials were mixed together to thereby prepare a 3.7% by mass solution. The solution was filtered with a polytetrafluoroethylene-made micro filter having a pore size of 0.2 μm, to thereby prepare a resist underlayer film-forming composition.

### Example 2

To 1.85 g of the solution containing 0.31 g of the copolymer prepared in Synthesis Example 1 (solvent: PGME used for the synthesis) were added 8.09 g of PGME, 1.12 g of propylene glycol monomethyl ether acetate, 0.12 g of 1,3,4,6-tetrakis(methoxymethyl)glycoluril (trade name: Powderlink 1174, available from Nihon Cytec Industries Inc.), 0.0078 g of pyridinium-p-toluenesulfonate, and 0.00031 g of a surfactant (trade name: R-30N, available from DIC Corporation). These materials were mixed together to thereby prepare a 3.7% by mass solution. The solution was filtered with a polytetrafluoroethylene-made micro filter having a pore size of 0.2 μm, to thereby prepare a resist underlayer film-forming composition.

### Comparative Example 1

To 1.79 g of the solution containing 0.30 g of the copolymer prepared in Synthesis Example 2 (solvent: PGME used for the synthesis) were added 6.42 g of PGME, 0.93 g of propylene glycol monomethyl ether acetate, 0.075 g of 1,3,4,6-tetrakis(methoxymethyl)glycoluril (trade name: Powderlink 1174, available from Nihon Cytec Industries Inc.), 0.0074 g of pyridinium-p-toluenesulfonate, and 0.00030 g of a surfactant (trade name: R-30N, available from DIC Corporation). These materials were mixed together to thereby prepare a 3.8% by mass solution. The solution was filtered with a polytetrafluoroethylene-made micro filter having a pore size of 0.2 μm, to thereby prepare a resist underlayer film-forming composition.

### Comparative Example 2

To 1.61 g of the solution containing 0.27 g of the copolymer prepared in Synthesis Example 2 (solvent: PGME used for the synthesis) were added 6.66 g of PGME, 0.94 g of propylene glycol monomethyl ether acetate, 0.11 g of 1,3,4,6-tetrakis(methoxymethyl)glycoluril (trade name: Powderlink 1174, available from Nihon Cytec Industries Inc.), 0.0067 g of pyridinium-p-toluenesulfonate, and 0.00027 g of a surfactant (trade name: R-30N, available from DIC Corporation). These materials were mixed together to thereby prepare a 3.8% by mass solution. The solution was filtered with a polytetrafluoroethylene-made micro filter having a pore size of 0.2 μm, to thereby prepare a resist underlayer film-forming composition.

[Test for Elution in Photoresist Solvent]

Each of the resist underlayer film-forming compositions of Examples 1 and 2 and Comparative Examples 1 and 2 was applied onto a silicon wafer with a spinner. Thereafter, the composition was baked on a hot plate at a temperature of 205° C. for one minute, to thereby form a resist underlayer film (thickness: 0.2 μm) on the silicon wafer. The resist underlayer film was immersed in solvents used for a photoresist solution; i.e., PGME and propylene glycol monomethyl ether acetate, and the film was found to be insoluble in these two solvents. In addition, the resist underlayer film was immersed in an alkaline developer for photoresist development (i.e., 2.38% by mass aqueous tetramethylammonium hydroxide solution), and the film was found to be insoluble in the developer.

[Test for Optical Parameters]

Each of the resist underlayer film-forming compositions of Examples 1 and 2 and Comparative Examples 1 and 2 was applied onto a silicon wafer with a spinner. Thereafter, the composition was baked on a hot plate at a temperature of 205° C. for one minute, to thereby form a resist underlayer film (thickness: 0.1 μm) on the silicon wafer. Subsequently, the refractive index (n value) and attenuation coefficient (k value) of the resist underlayer film were measured at wavelengths of 193 nm and 248 nm with an optical ellipsometer (VUV-VASE VU-302, available from J. A. Woollam). The results are shown in Table 1 below. The k values at wavelengths of 193 nm and 248 nm are preferably 0.1 or more in view that the resist underlayer film has a sufficient anti-reflective function.

[Measurement of Dry Etching Rate]

Each of the resist underlayer film-forming compositions of Examples 1 and 2 and Comparative Examples 1 and 2 was used to form a resist underlayer film on a silicon wafer in the same manner as described above. The dry etching rate of the resist underlayer film was measured with an RIE system available from SAMCO Inc. under the condition that N₂ was used as a dry etching gas. Meanwhile, a photoresist solution (trade name: V146G, available from JSR Corporation) was applied onto a silicon wafer with a spinner, and then the photoresist was baked on a hot plate at a temperature of 110° C. for one minute, to thereby form a photoresist film. The dry etching rate of the photoresist film was measured with the aforementioned RIE system available from SAMCO Inc. under the condition that N₂ was used as a dry etching gas. The dry etching rate of the resist underlayer film was calculated by taking the dry etching rate of the photoresist film as 1.00. The results are shown in Table 1 below as “Etch selectivity.”

(Measurement of Amount of Sublimate)

Each of the resist underlayer film-forming compositions of Examples 1 and 2 and Comparative Examples 1 and 2 was applied to a silicon wafer having a diameter of 4 inches by spin coating at a rotation speed of 1,500 rpm for 60 seconds. The composition-applied silicon wafer was placed in a sublimate amount measuring apparatus integrated with a hot plate (see International Publication WO 2007/111147 pamphlet), and then baked for 120 seconds, to thereby collect a sublimate on a QCM (quartz crystal microbalance) sensor; i.e., a quartz oscillator having an electrode. The QCM sensor can measure a minute change in mass by utilizing its property that deposition of a sublimate on the surface (electrode) of the quartz oscillator causes a change (decrease) in the frequency of the quartz oscillator in accordance with the mass of the sublimate.

Detailed measurement procedure is as follows. The hot plate of the sublimate amount measuring apparatus was heated to 205° C., and the flow rate of a pump was set to 1 m³/s. The apparatus was left to stand for the first 60 seconds for stabilizing the apparatus. Immediately thereafter, the silicon wafer coated with the resist underlayer film-forming composition was quickly placed on the hot plate through a sliding opening. The sublimate generated from 60 seconds to 180 seconds after the placement (during 120 seconds) was collected. The resist underlayer film formed on the silicon wafer had a thickness of 100 nm.

A flow attachment (detection portion) connecting the QCM sensor of the sublimate amount measuring apparatus and a collection funnel was used without attachment of a nozzle. Thus, a gas is inflowed without being narrowed from a flow channel (diameter: 32 mm) of a chamber unit located 30 mm distant from the sensor (quartz oscillator). The electrode of the QCM sensor was formed of a material containing silicon and aluminum as main components (AlSi). In the QCM sensor used, the diameter of the quartz oscillator (sensor diameter) was 14 mm, the diameter of the electrode on the surface of the quartz oscillator was 5 mm, and the resonance frequency was 9 MHz.

The thus-measured frequency change was converted to gram on the basis of the eigenvalue of the quartz oscillator used for the measurement, to thereby clarify the relationship between the amount of a sublimate from one silicon wafer coated with the resist underlayer film and the elapsed time. Table 1 shows the amount of a sublimate generated from each of the resist underlayer film-forming compositions of Examples 1 and 2 and Comparative Examples 1 and 2 during 120 seconds, relative to the amount of a sublimate generated from the resist underlayer film-forming composition of Comparative Example 1 during 120 seconds (taken as 1.00). The results indicated that the amount of a sublimate generated from each of the resist underlayer film-forming compositions of Examples 1 and 2 is smaller than that of a sublimate generated from each of the resist underlayer film-forming compositions of Comparative Examples 1 and 2.

TABLE 1

| | | | | Optical parameters | | | | | Amount |
|---|---|---|---|---|---|---|---|---|---|
| | Solvent resistance | | | 193 nm | | 248 nm | | Etch | of |
| | PGME | PGMEA | NMD-3 | n value | k value | n value | k value | selectivity | sublimate |
| Example 1 | ◯ | ◯ | ◯ | 1.70 | 0.16 | 1.57 | 0.22 | 3.44 | 0.77 |
| Example 2 | ◯ | ◯ | ◯ | 1.71 | 0.15 | 1.57 | 0.21 | 3.37 | 0.62 |
| Comparative | ◯ | ◯ | ◯ | 1.69 | 0.06 | 1.63 | 0.41 | 2.80 | 1.00 |
| Example 1 | | | | | | | | | |
| Comparative | ◯ | ◯ | ◯ | 1.70 | 0.07 | 1.64 | 0.36 | 2.81 | 1.05 |
| Example 2 | | | | | | | | | |

As shown in Table 1 above, the resist underlayer film formed from each of the resist underlayer film-forming compositions of Examples 1 and 2 exhibits k values of 0.1 or more at wavelengths of 193 nm and 248 nm. The results indicate that the resist underlayer film has an anti-reflective function in a light exposure process using any of ArF excimer laser and KrF excimer laser. In contrast, the resist underlayer film formed from each of the resist underlayer film-forming compositions of Comparative Examples 1 and 2 exhibited a k value of less than 0.1 at a wavelength of 193 nm. The resist underlayer film formed from each of the resist underlayer film-forming compositions of Examples 1 and 2 exhibits a dry etching rate much higher than that of the aforementioned photoresist film, and a dry etching rate higher than that of the resist underlayer film formed from each of the resist underlayer film-forming compositions of Comparative Examples 1 and 2. The results also indicated that the amount of a sublimate generated during formation of a resist underlayer film from each of the resist underlayer film-forming compositions of Examples 1 and 2 is significantly smaller than the amount of a sublimate generated during formation of a resist underlayer film from each of the resist underlayer film-forming compositions of Comparative Examples 1 and 2. These results indicated that the resist underlayer film-forming compositions of Examples 1 and 2 achieve reduced sublimation and high dry etching rate, as compared with the resist underlayer film-forming compositions of Comparative Examples 1 and 2, and can form a resist underlayer film having an anti-reflective function in a light exposure process using any of ArF excimer laser and KrF excimer laser.

(Evaluation of Photoresist Pattern Shape)

Each of the resist underlayer film-forming compositions of Example 2 and Comparative Example 2 was applied onto a silicon wafer with a spinner. Thereafter, the composition was baked on a hot plate at a temperature of 205° C. for one minute, to thereby form a resist underlayer film having a thickness of 0.1 μm on the silicon wafer. A commercially available photoresist solution (trade name: SEPR-602, available from Shin-Etsu Chemical Co., Ltd.) was applied onto the resist underlayer film with a spinner, and the photoresist was baked on a hot plate at a temperature of 110° C. for 60 seconds, to thereby form a photoresist film (thickness: 0.26 μm).

Subsequently, light exposure was performed with a scanner NSRS205C available from Nikon Corporation (wavelength: 248 nm, NA: 0.75, a: 0.43/0.85 (ANNULAR)) through a photomask designed to form nine lines in the photoresist after development so as to achieve a line width of 0.11 μm and an interline width of 0.11 μm; i.e., 0.11 μm L/S (dense line). Thereafter, post exposure bake (PEB) was performed on a hot plate at a temperature of 110° C. for 60 seconds. After cooling, development was performed by an industrially standardized 60-second single paddle process using a 0.26 N aqueous tetramethylammonium hydroxide solution as a developer.

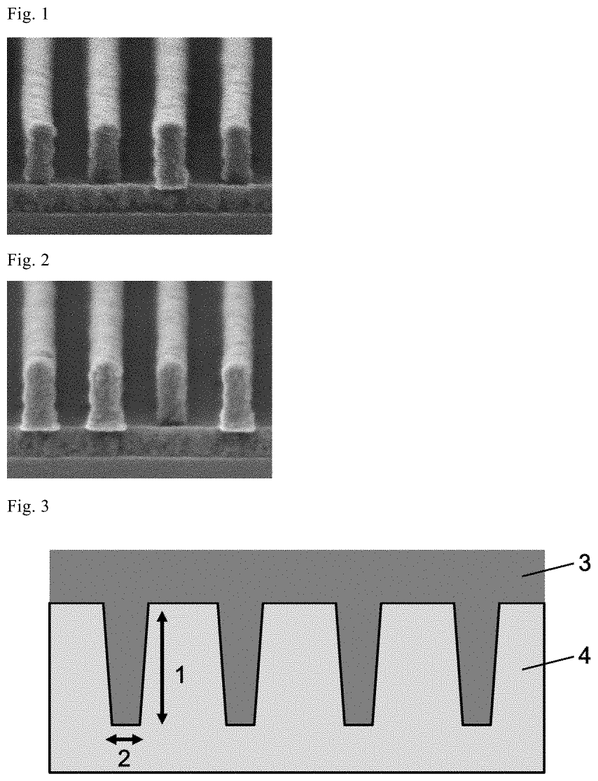

After completion of the development, a cross section of the resultant photoresist pattern in a direction perpendicular to the substrate (i.e., silicon wafer) was observed with a scanning electron microscope (SEM). Consequently, the photoresist pattern formed on the resist underlayer film formed from the resist underlayer film-forming composition of Example 2 was found to have a cross section of good straight skirt shape; i.e., substantially rectangular shape. In contrast, the photoresist pattern formed on the resist underlayer film formed from the resist underlayer film-forming composition of Comparative Example 2 was found to have a cross section of skirt shape; i.e., non-rectangular shape. FIGS. 1 and 2 are SEM images of cross sections of the photoresist patterns finally formed on the substrates by using the resist underlayer film-forming compositions of Example 2 and Comparative Example 2, respectively.

[Test for Filling Property (Fillability)]

Each of the resist underlayer film-forming compositions of Examples 1 and 2 was applied with a spinner onto a silicon wafer having a plurality of trenches (width: 0.04 μm, depth: 0.3 μm) and having an SiO₂ film formed on its surface (hereinafter the silicon wafer will be abbreviated as “SiO₂ wafer”). Thereafter, the composition was baked on a hot plate at a temperature of 205° C. for one minute, to thereby form a resist underlayer film (thickness: 0.1 μm). FIG. 3 schematically shows an SiO₂ wafer 4 used for this test, and a resist underlayer film 3 formed on the SiO₂ wafer 4. The SiO₂ wafer 4 has a dense pattern of trenches. In the dense pattern, the distance between the center of a trench and the center of the adjacent trench is three times the width of the trench. As shown in FIG. 3, each trench of the SiO₂ wafer 4 has a depth 1 of 0.3 μm and a width 2 of 0.04 μm.

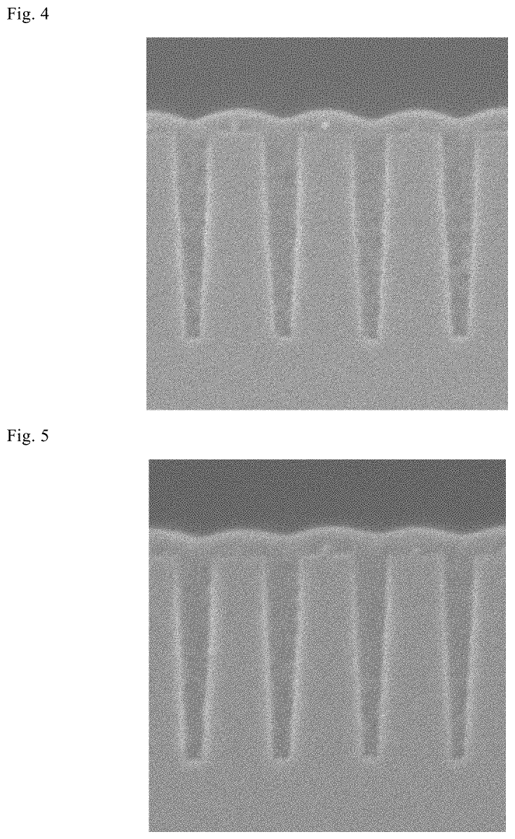

As described above, each of the resist underlayer film-forming compositions of Examples 1 and 2 was applied onto the SiO₂ wafer and then baked, to thereby form a resist underlayer film. A cross section of the resultant SiO₂ wafer was observed with a scanning electron microscope (SEM), to thereby evaluate the SiO₂ wafer trench-filling property (fillability) of the resist underlayer film. The results are shown in FIG. 4 (Example 1) and FIG. 5 (Example 2). As shown in FIGS. 4 and 5, no voids were observed in the interiors of the trenches, and the interiors of the trenches were filled with the resist underlayer film; i.e., the entire trenches were completely filled with the film.

### DESCRIPTION OF THE REFERENCE NUMERALS

1: Depth of trench of SiO₂ wafer
2: Width of trench of SiO₂ wafer
3: Resist underlayer film
4: SiO₂ wafer

1. A resist underlayer film-forming composition comprising a solvent and a copolymer including a structural unit of the following Formula (1): 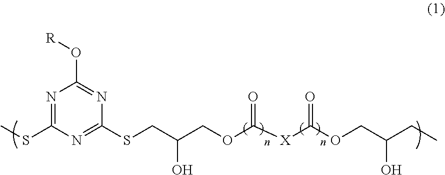
wherein X is a divalent chain hydrocarbon group having a carbon atom number of 2 to 10, and the divalent chain hydrocarbon group optionally has at least one sulfur atom or oxygen atom in a main chain, or optionally has at least one hydroxy group as a substituent; R is a chain hydrocarbon group having a carbon atom number of 1 to 10; and each n is 0 or 1.

2. The resist underlayer film-forming composition according to claim 1, wherein the copolymer is a reaction product between a dithiol compound of the following Formula (2) and a diglycidyl ether compound or diglycidyl ester compound of the following Formula (3): 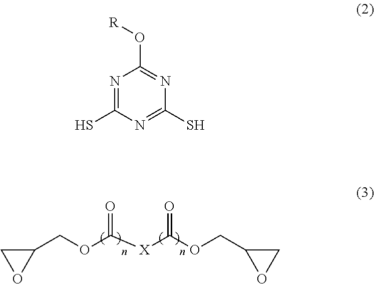
wherein X, R, and each n have the same meanings as defined above in Formula (1).

3. The resist underlayer film-forming composition according to claim 1, wherein the composition further comprises a crosslinkable compound.

4. The resist underlayer film-forming composition according to claim 1, wherein the composition further comprises a thermal acid generator.

5. The resist underlayer film-forming composition according to claim 1, wherein the composition further comprises a surfactant.

6. A method for forming a photoresist pattern used for production of a semiconductor device, the method comprising a step of applying the resist underlayer film-forming composition according to claim 1 onto a semiconductor substrate having a recess on its surface, and then baking the composition, to thereby form a resist underlayer film that fills at least the recess; a step of forming a photoresist layer on the resist underlayer film; a step of exposing, to light, the semiconductor substrate coated with the resist underlayer film and the photoresist layer; and a step of developing the photoresist layer after the light exposure.
